(19) United States
(12) Patent Application Publication
(10) Pub. No.: US 2021/0165628 A1
(43) Pub. Date: Jun. 3, 2021

(54) SYSTEMS AND METHODS FOR SELECTING AND SHARING AUDIO PRESETS

(71) Applicant: AUDIBLE REALITY INC., Montreal (CA)

(72) Inventor: Matthew BOERUM, Brighton, MA (US)

(21) Appl. No.: 17/111,098

(22) Filed: Dec. 3, 2020

Related U.S. Application Data
(60) Provisional application No. 62/943,144, filed on Dec. 3, 2019.
(60) Provisional application No. 63/029,646, filed on May 25, 2020.
(60) Provisional application No. 63/030,251, filed on May 26, 2020.

(51) Int. Cl. G06F 3/16; H03G 5/16; H03G 5/00

(52) U.S. Cl. CPC G06F 3/165; H03G 5/005; H03G 5/165

(57) ABSTRACT

There is disclosed a method and system for selecting an audio preset for an audio processing engine. A selection of an audio track may be received. Audio corresponding to the audio track may be output. A selection to display audio presets may be received. A carousel user interface may be displayed, where the carousel user interface comprises images corresponding to audio presets. A selection of an audio preset may be received via the carousel user interface. The audio preset may be applied to the audio processing engine. The audio processing engine may generate an audio stream based on the audio track. The audio stream may be output.

### CROSS-REFERENCE TO RELATED APPLICATIONS

This application claims the benefit of and priority to U.S. Provisional Patent Application No. 63/030,251, filed on May 26, 2020, U.S. Provisional Patent Application No. 63/029,646, filed on May 25, 2020, and U.S. Provisional Patent Application No. 62/943,144, filed on Dec. 3, 2019, each of which is incorporated by reference herein in its entirety.

### BACKGROUND

During audio production, various audio tracks are recorded, then mixed and mastered, and a final master is created. During the audio mastering various filters, effects, equalizers, compressors, etc. may be applied to the audio tracks to generate the final master. That final master might not represent the playback conditions of the original recording and/or may be limited by audio processing technology to accurately reproduce the sound that was recorded. It is not possible to change the settings of the recording because those settings are essentially “recorded” into the physical (or digital) final master. The elements of audio production (the underlying digital audio processes) are captured in a way that they cannot be controlled, or even accessed after the mastering process.

### SUMMARY

An audio processing engine, such as a mono, stereo, and/or 3D audio processing engine may be used during mastering. The audio processing engine may be incorporated in a digital audio workstation (DAW) used to master the audio tracks. The audio processing engine may be configured to save and/or recall saved parameter settings, referred to herein as “audio presets.” All or a portion of the settings used in the DAW during the mastering process may be captured in an audio preset. The audio preset may contain saved parameter and control settings for the audio signal processing chain used in the audio production process. The audio presets may include controls for the audio processing engine and/or an artificial intelligence (AI) audio processor. The audio presets may control a single configurable parameter to various configurable parameters of the audio processing engine.

A user may apply the audio preset when listening to audio. The audio processing engine may use the settings from the audio preset to generate an output audio stream from the audio. The user may modify the audio preset while listening to the audio stream. Rather than applying additional filters, effects, etc. to the final master, the audio processing engine may apply the audio controls indicated in the preset to the original audio. The end-user can adjust the preset to modify the audio in the same way that the mastering engineer can apply audio controls to the audio during the mastering process.

A user listening to audio content may wish to interact with the audio by auditioning and/or selecting an audio preset to be applied to the audio content in real-time that she/he is listening to. She/he may also wish to refine or adjust the audio preset of any of the individual audio processing engine parameters. She/he may wish to add new audio presets, assets, programming, images, or other processes, content or commands to audition the resultant audio processing applied to the sound. After selecting an audio preset, creating a new preset, or otherwise modifying parameters in the audio engine, the user may wish to share, save, sell and/or otherwise distribute the audio preset and/or modifications with another user.

An audio application may be executed on a user's mobile device. The audio application may play audio content such as music or any other audio track. The audio application may retrieve and/or play audio content from a third-party audio content service located remotely from the user's mobile device. The audio application may include an audio processing engine that can be applied to an audio track such as an audio stream. The audio processing engine may convert a mono or stereo audio stream to a 3D audio stream. The 3D audio stream may then be output to one or more speakers, a headset, a wirelessly connected device such as a Bluetooth speaker, and/or any other audio device.

A user may be listening to audio content, such as music or any other type of audio track, that is not being processed by the audio processing engine. The user may wish to have the audio processing engine apply an audio preset to the audio track, such as an audio preset causing the audio processing engine to convert the audio track into a 3D audio stream. The user may select an element of a user interface corresponding to the currently playing audio track. In response to the selection a user interface displaying audio presets for the audio processing engine may be displayed. An image corresponding to each available audio preset may be displayed. The images may be displayed in a carousel interface, which allows the user to scroll through each of the audio presets.

After the user selects an audio preset, the audio preset may be applied to the audio processing engine, and the audio processing engine may apply the audio preset to the audio track to generate an audio stream. The audio stream may be a 3D audio stream. The audio stream may then be output to the user. An indication of the selected audio preset, such as the image associated with the audio preset, may be displayed on the user interface.

While listening to the audio stream, the user may wish to share the audio stream and the audio preset being applied to the audio stream with another user. The user may select an element on the user interface to indicate that they wish to share their current audio stream and audio preset. An indication of the currently playing audio track and the current audio preset may be transmitted to a server. A uniform resource locator (URL) may be generated and transmitted to the other user. When selected by the other user, the URL may cause the other user's device to download the audio preset and begin playing the shared audio track. The audio preset may be applied to the audio processing engine to output an audio stream. The audio stream and the processing applied by the shared audio preset may be output to the other user.

According to a first broad aspect of the present technology, there is provided a method comprising: receiving user input indicating a selection of an audio track; retrieving an audio preset corresponding to the audio track, wherein the audio preset was created by an audio processing engine, wherein the audio preset comprises parameters for the audio processing engine, and wherein the parameters correspond to an audio signal processing chain used to create the audio track; applying the audio preset to the audio processing engine; generating, by the audio processing engine and based on the audio track, an audio stream; and outputting the audio stream.

In some implementations of the method, the method further comprises receiving user input modifying the audio preset; applying the modified audio preset to the audio processing engine; generating, by the audio processing engine and based on the audio, a second audio stream; and outputting the second audio stream.

According to another broad aspect of the present technology, there is provided a method comprising: receiving user input indicating a selection of an audio track; outputting audio corresponding to the audio track; displaying a user interface for controlling playback of the audio track; receiving a selection to display audio presets; retrieving a plurality of available audio presets; retrieving a plurality of images, wherein each image of the plurality of images corresponds to a respective audio preset of the plurality of available audio presets; displaying a carousel user interface comprising at least one image of the plurality of images; receiving, via the carousel user interface, a selection of an audio preset of the plurality of available audio presets; determining whether a user has access to the audio preset; after determining that the user has access to the audio preset, applying the audio preset to an audio processing engine; generating, by the audio processing engine and based on the audio track, an audio stream; and outputting the audio stream.

In some implementations of the method, the method further comprises receiving, via the carousel user interface, a selection of a second audio preset of the plurality of available audio presets; applying the second audio preset to the audio processing engine; generating, by the audio processing engine and based on the audio, a second audio stream; and outputting the second audio stream.

In some implementations of the method, determining whether the user has access to the audio preset comprises determining whether the user has subscribed to a subscription providing access to the audio preset.

In some implementations of the method, each audio preset of the plurality of available audio presets comprises settings for one or more adjustable parameters of the audio processing engine.

In some implementations of the method, receiving the selection of the audio preset comprises receiving an indication that the user has placed an image corresponding to the audio preset in a central portion of the carousel user interface.

In some implementations of the method, the carousel interface comprises a scrollable interface for scrolling through the plurality of images.

According to another broad aspect of the present technology, there is provided a system comprising a user device, the user device comprising at least one processor, and memory storing a plurality of executable instructions which, when executed by the at least one processor, cause the user device to: receive a request to share an audio preset being applied to an audio processing engine, wherein the audio processing engine is outputting an audio stream based on an audio track; transmit, to an audio preset storage system, the audio preset; transmit, to the audio preset storage system, an indication of the audio track; receive, from the audio preset storage system, a uniform resource locator (URL) corresponding to the audio preset and the indication of the audio track; and transmit, to a second user device, the URL.

In some implementations of the system, the audio preset comprises a plurality of settings for adjustable parameters of the audio processing engine.

In some implementations of the system, the instructions, when executed by the at least one processor of the user device, cause the first user device to transmit the audio preset to the audio preset storage system in an encrypted format.

In some implementations of the system, the instructions, when executed by the at least one processor of the user device, cause the user device to transmit, to the audio preset storage system, an image corresponding to the audio preset.

According to another broad aspect of the present technology, there is provided a system comprising a user device, the user device comprising at least one processor, and memory storing a plurality of executable instructions which, when executed by the at least one processor, cause the user device to: receive a uniform resource locator (URL); retrieve, based on the URL, an audio preset; retrieve, based on the URL, an audio track; apply the audio preset to an audio processing engine; generate, by the audio processing engine and based on the audio track, an audio stream; and output the audio stream.

In some implementations of the system, the instructions, when executed by the at least one processor of the user device, cause the user device to display the image overlaid on a button.

In some implementations of the system, the instructions, when executed by the at least one processor of the user device, cause the user device to retrieve the audio preset in an encrypted format.

In some implementations of the system, the audio processing engine is configured to decrypt the audio preset in the encrypted format.

In some implementations of the system, the instructions, when executed by the at least one processor of the user device, cause the user device to: retrieve, based on the URL, an image associated with the audio preset; and display a user interface comprising the image.

According to another broad aspect of the present technology, there is provided a method comprising receiving user input indicating a selection of an audio track; outputting audio corresponding to the audio track; displaying a user interface for controlling playback of the audio track; receiving a selection to display audio presets; retrieving a plurality of available audio presets; retrieving a plurality of images, wherein each image of the plurality of images corresponds to a respective audio preset of the plurality of available audio presets; displaying a carousel user interface comprising at least one image of the plurality of images; receiving, via the carousel user interface, a selection of an audio preset of the plurality of available audio presets; determining whether a user has access to the audio preset; after determining that the user does not have access to the audio preset, applying the audio preset to an audio processing engine for up to a predetermined amount of time; generating, by the audio processing engine and based on the audio, an audio stream; outputting the audio stream; after the predetermined amount of time, reverting to outputting the audio corresponding to the audio track; receiving a confirmation that the user has purchased the audio preset; and after receiving the confirmation, outputting the audio stream.

In some implementations of the method, the method further comprises receiving a user selection to subscribe to a subscription comprising the audio preset.

In some implementations of the method, the method further comprises receiving, via the carousel user interface, a selection of a second audio preset of the plurality of available audio presets; applying the second audio preset to the audio processing engine; generating, by the audio engine and based on the audio, a second audio stream; and outputting the second audio stream.

In some implementations of the method, receiving the selection of the audio preset comprises receiving an indication that the user has placed an image corresponding to the audio preset in a highlighted portion of the carousel user interface.

According to another broad aspect of the present technology, there is provided a system comprising: at least one processor, and memory storing a plurality of executable instructions which, when executed by the at least one processor, cause the system to: receive user input indicating a selection of an audio track; retrieve an audio preset corresponding to the audio track, wherein the audio preset was created by an audio processing engine, wherein the audio preset comprises parameters for the audio processing engine, and wherein the parameters correspond to an audio signal processing chain used to create the audio track; apply the audio preset to the audio processing engine; generate by the audio processing engine and based on the audio track, an audio stream; and output the audio stream.

In some implementations of the system, the instructions, when executed by the at least one processor, cause the system to: receive user input modifying the audio preset; apply the modified audio preset to the audio processing engine; generate, by the audio processing engine and based on the audio, a second audio stream; and output the second audio stream.

In some implementations of the system, the instructions, when executed by the at least one processor, cause the system to: display a carousel user interface comprising a plurality of images corresponding to audio presets; and receive, via the carousel user interface, a selection of the audio preset.

In some implementations of the system, the instructions, when executed by the at least one processor, cause the system to: determine whether a user has access to the audio preset; and after determining that the user has access to the audio preset, apply the audio preset to the audio processing engine.

In some implementations of the system, the instructions, when executed by the at least one processor, cause the system to: determine whether a user has access to the audio preset; and after determining that the user does not have access to the audio preset, output the audio stream for up to a predetermined amount of time.

In some implementations of the system, the instructions, when executed by the at least one processor, cause the system to after the predetermined amount of time, revert to outputting audio corresponding to the audio track.

In some implementations of the system, the instructions, when executed by the at least one processor, cause the system to: receive a confirmation that the user has purchased the audio preset; and after receiving the confirmation, output the audio stream.

Various implementations of the present technology provide a non-transitory computer-readable medium storing program instructions for executing one or more methods described herein, the program instructions being executable by a processor of a computer-based system.

Various implementations of the present technology provide a computer-based system, such as, for example, but without being limitative, an electronic device comprising at least one processor and a memory storing program instructions for executing one or more methods described herein, the program instructions being executable by the at least one processor of the electronic device.

In the context of the present specification, unless expressly provided otherwise, a computer system may refer, but is not limited to, an “electronic device,” a “computing device,” an “operation system,” a “system,” a “computer-based system,” a “computer system,” a “network system,” a “network device,” a “controller unit,” a “monitoring device,” a “control device,” a “server,” and/or any combination thereof appropriate to the relevant task at hand.

In the context of the present specification, unless expressly provided otherwise, the expression “computer-readable medium” and “memory” are intended to include media of any nature and kind whatsoever, non-limiting examples of which include RAM, ROM, disks (e.g., CD-ROMs, DVDs, floppy disks, hard disk drives, etc.), USB keys, flash memory cards, solid state-drives, and tape drives. Still in the context of the present specification, “a” computer-readable medium and “the” computer-readable medium should not be construed as being the same computer-readable medium. To the contrary, and whenever appropriate, “a” computer-readable medium and “the” computer-readable medium may also be construed as a first computer-readable medium and a second computer-readable medium.

In the context of the present specification, unless expressly provided otherwise, the words “first,” “second,” “third,” etc. have been used as adjectives only for the purpose of allowing for distinction between the nouns that they modify from one another, and not for the purpose of describing any particular relationship between those nouns.

Additional and/or alternative features, aspects and advantages of implementations of the present technology will become apparent from the following description, the accompanying drawings, and the appended claims.

### BRIEF DESCRIPTION OF THE DRAWINGS

For a better understanding of the present technology, as well as other aspects and further features thereof, reference is made to the following description which is to be used in conjunction with the accompanying drawings, where:

FIG. 1 is a block diagram of an example computing environment in accordance with various embodiments of the present technology;

FIG. 2 is a diagram of a system for distributing audio presets in accordance with various embodiments of the present technology;

FIG. 3 illustrates a user interface for an audio application in accordance with various embodiments of the present technology;

FIG. 4 illustrates a user interface for selecting an audio preset in accordance with various embodiments of the present technology;

FIGS. 5A-B illustrate a flow diagram of a method for selecting an audio preset in accordance with various embodiments of the present technology;

FIG. 6 illustrates a flow diagram of a method for sharing an audio preset in accordance with various embodiments of the present technology;

FIG. 7 illustrates a flow diagram of a method for storing audio settings in accordance with various embodiments of the present technology;

FIG. 8 illustrates a flow diagram of a method for outputting an audio stream in accordance with various embodiments of the present technology;

FIG. 9 illustrates a user interface for sharing an audio preset in accordance with various embodiments of the present technology.

FIG. 10 illustrates a user interface for receiving a shared audio preset in accordance with various embodiments of the present technology.

### DETAILED DESCRIPTION

The examples and conditional language recited herein are principally intended to aid the reader in understanding the principles of the present technology and not to limit its scope to such specifically recited examples and conditions. It will be appreciated that those skilled in the art may devise various arrangements which, although not explicitly described or shown herein, nonetheless embody the principles of the present technology and are included within its spirit and scope.

Furthermore, as an aid to understanding, the following description may describe relatively simplified implementations of the present technology. As persons skilled in the art would understand, various implementations of the present technology may be of greater complexity.

In some cases, what are believed to be helpful examples of modifications to the present technology may also be set forth. This is done merely as an aid to understanding, and, again, not to define the scope or set forth the bounds of the present technology. These modifications are not an exhaustive list, and a person skilled in the art may make other modifications while nonetheless remaining within the scope of the present technology. Further, where no examples of modifications have been set forth, it should not be interpreted that no modifications are possible and/or that what is described is the sole manner of implementing that element of the present technology.

Moreover, all statements herein reciting principles, aspects, and implementations of the present technology, as well as specific examples thereof, are intended to encompass both structural and functional equivalents thereof, whether they are currently known or developed in the future. Thus, for example, it will be appreciated by those skilled in the art that any block diagrams herein represent conceptual views of illustrative circuitry embodying the principles of the present technology. Similarly, it will be appreciated that any flowcharts, flow diagrams, state transition diagrams, pseudo-code, and the like represent various processes which may be substantially represented in computer-readable media and so executed by a computer or processor, whether or not such computer or processor is explicitly shown.

The functions of the various elements shown in the figures, including any functional block labeled as a “processor,” may be provided through the use of dedicated hardware as well as hardware capable of executing software in association with appropriate software. When provided by a processor, the functions may be provided by a single dedicated processor, by a single shared processor, or by a plurality of individual processors, some of which may be shared. In some embodiments of the present technology, the processor may be a general purpose processor, such as a central processing unit (CPU) or a processor dedicated to a specific purpose, such as a digital signal processor (DSP). Moreover, explicit use of the term a “processor” should not be construed to refer exclusively to hardware capable of executing software, and may implicitly include, without limitation, application specific integrated circuit (ASIC), field programmable gate array (FPGA), read-only memory (ROM) for storing software, random access memory (RAM), and non-volatile storage. Other hardware, conventional and/or custom, may also be included.

Software modules, or simply modules which are implied to be software, may be represented herein as any combination of flowchart elements or other elements indicating performance of process steps and/or textual description. Such modules may be executed by hardware that is expressly or implicitly shown. Moreover, it should be understood that one or more modules may include for example, but without being limitative, computer program logic, computer program instructions, software, stack, firmware, hardware circuitry, or a combination thereof.

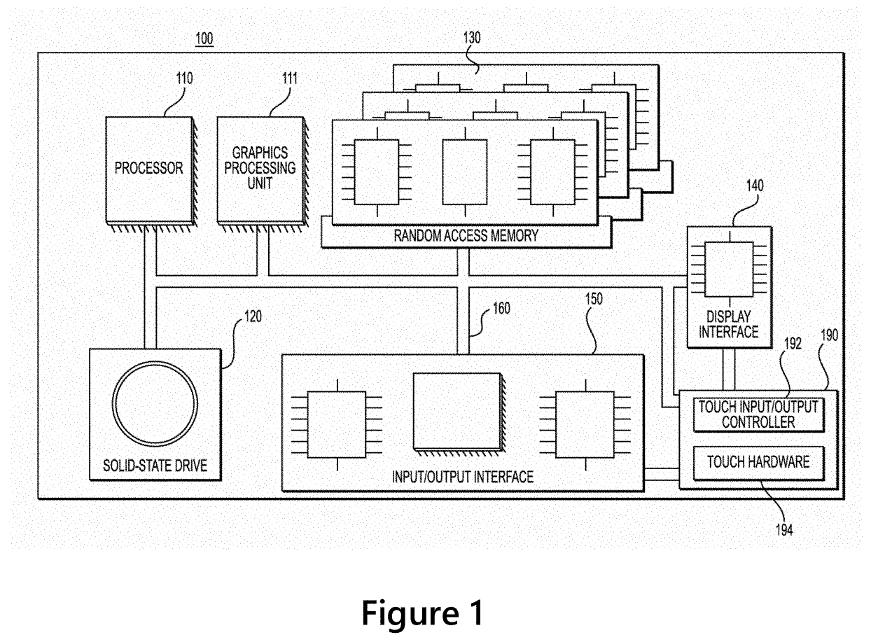

FIG. 1 illustrates a computing environment 100, which may be used to implement and/or execute any of the methods described herein. In some embodiments, the computing environment 100 may be implemented by any of a conventional personal computer, a computer dedicated to managing network resources, a network device and/or an electronic device (such as, but not limited to, a mobile device, a tablet device, a server, a controller unit, a control device, etc.), and/or any combination thereof appropriate to the relevant task at hand. In some embodiments, the computing environment 100 comprises various hardware components including one or more single or multi-core processors collectively represented by processor 110, a solid-state drive 120, a random access memory 130, and an input/output interface 150. The computing environment 100 may be a generic computer system. The computing environment 100 may be a computer system specifically designed to process audio and/or operate a machine learning algorithm (MLA).

In some embodiments, the computing environment 100 may also be a subsystem of one of the above-listed systems. In some other embodiments, the computing environment 100 may be an “off-the-shelf” generic computer system. In some embodiments, the computing environment 100 may also be distributed amongst multiple systems. The computing environment 100 may also be specifically dedicated to the implementation of the present technology. As a person in the art of the present technology may appreciate, multiple variations as to how the computing environment 100 is implemented may be envisioned without departing from the scope of the present technology.

Those skilled in the art will appreciate that processor 110 is generally representative of a processing capability. In some embodiments, in place of or in addition to one or more conventional Central Processing Units (CPUs), one or more specialized processing cores may be provided. For example, one or more Graphic Processing Units 111 (GPUs), Tensor Processing Units (TPUs), and/or other so-called accelerated processors (or processing accelerators) may be provided in addition to or in place of one or more CPUs.

System memory will typically include random access memory 130, but is more generally intended to encompass any type of non-transitory system memory such as static random access memory (SRAM), dynamic random access memory (DRAM), synchronous DRAM (SDRAM), read-only memory (ROM), or a combination thereof. Solid-state drive 120 is shown as an example of a mass storage device, but more generally such mass storage may comprise any type of non-transitory storage device configured to store data, programs, and other information, and to make the data, programs, and other information accessible via a system bus 160. For example, mass storage may comprise one or more of a solid state drive, hard disk drive, a magnetic disk drive, and/or an optical disk drive.

Communication between the various components of the computing environment 100 may be enabled by a system bus 160 comprising one or more internal and/or external buses (e.g., a PCI bus, universal serial bus, IEEE 1394 “Firewire” bus, SCSI bus, Serial-ATA bus, ARINC bus, etc.), to which the various hardware components are electronically coupled.

The input/output interface 150 may allow enabling networking capabilities such as wired or wireless access. As an example, the input/output interface 150 may comprise a networking interface such as, but not limited to, a network port, a network socket, a network interface controller and the like. Multiple examples of how the networking interface may be implemented will become apparent to the person skilled in the art of the present technology. For example the networking interface may implement specific physical layer and data link layer standards such as Ethernet, Fibre Channel, Wi-Fi, Token Ring or Serial communication protocols. The specific physical layer and the data link layer may provide a base for a full network protocol stack, allowing communication among small groups of computers on the same local area network (LAN) and large-scale network communications through routable protocols, such as Internet Protocol (IP).

The input/output interface 150 may be coupled to a touchscreen 190 and/or to the one or more internal and/or external buses 160. The touchscreen 190 may be part of the display. In some embodiments, the touchscreen 190 is the display. The touchscreen 190 may equally be referred to as a screen 190. In the embodiments illustrated in FIG. 1, the touchscreen 190 comprises touch hardware 194 (e.g., pressure-sensitive cells embedded in a layer of a display allowing detection of a physical interaction between a user and the display) and a touch input/output controller 192 allowing communication with the display interface 140 and/or the one or more internal and/or external buses 160. In some embodiments, the input/output interface 150 may be connected to a keyboard (not shown), a mouse (not shown) or a trackpad (not shown) allowing the user to interact with the computer system 100 in addition to or instead of the touchscreen 190.

According to some implementations of the present technology, the solid-state drive 120 stores program instructions suitable for being loaded into the random access memory 130 and executed by the processor 110 for executing acts of one or more methods described herein. For example, at least some of the program instructions may be part of a library or an application.

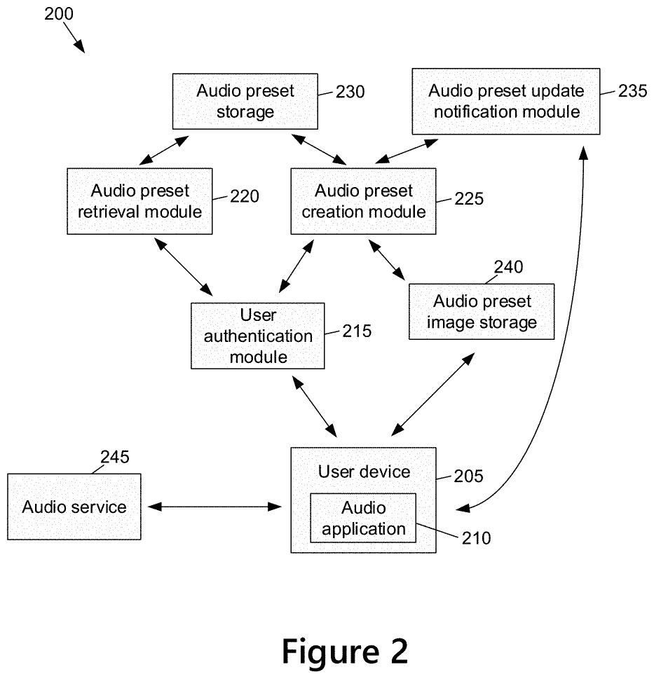

FIG. 2 is a diagram of a system 200 for distributing audio presets in accordance with various embodiments of the present technology. All or a portion of the modules executing in the system 200 may be executed by one or more cloud services. A user device 205, such as a smartphone, tablet, or any other computing environment 100, may execute an audio application 210 to play audio content such as, but without being limitative, a song, a podcast or an audio book. The audio application 210 may receive the audio content from an audio service 245. The audio service 245 may be a third-party audio service, such as an audio service that the user of the user device 205 subscribes to.

The audio service 245 may provide music, such as Spotify®, Deezer®, etc., audio books, such as Audible®, podcasts, and/or any other type of audio. The audio application 210 may provide a front-end for the audio service 245. The audio application 210 may be capable of receiving audio from multiple audio services 245. The user of the user device 205 may input credentials to the audio application 210 for each of the audio services 245 that the user subscribes to or otherwise enable the audio application 210 to access the audio services 245.

The audio application 210 may implement an audio processing engine. The audio processing engine may be executed on the device 205 and/or remotely from the device 205. The audio processing engine may convert the audio received from the audio service 245 to a 3D audio stream. Various parameters of the audio processing engine may be adjustable, such as digital audio signal processing parameters. The parameters of the audio processing engine may be adjusted manually by a user, automatically by a machine learning algorithm (MLA), and/or based on an audio preset. Each audio preset may include predefined settings for some or all of the adjustable parameters of the audio processing engine.

The audio processing engine in the audio application 210 may be a same audio processing engine used in a digital audio workstation (DAW) used during production of the audio. By using the same audio processing engine in the DAW and in the audio application 210, a listener using the audio application 210 may be able to adjust settings used in the DAW during production of the audio track.

Audio presets may be created, edited, managed, and/or stored using the system 200. It should be understood that the arrangement of systems illustrated in FIG. 2 is exemplary, and that any other suitable arrangement may be used. When a user requests to retrieve and/or create an audio preset, a message may be sent to the user authentication module 215. The user authentication module 215 may receive the message and authenticate the user of the user device 205. The user authentication module 215 may request authentication credentials from the user device 205, such as a username and/or password. The user device 205 may display an interface requesting that the user enter their credentials. The audio application 210 may store the authentication credentials.

After the user has been authenticated by the user authentication module 215, the user authentication module 215 may determine whether the user wishes to retrieve an audio preset or store an audio preset. Each audio preset may comprise a list of one or more settings for an audio processing engine. If the user wishes to receive an audio preset, the user authentication module 215 may transmit a request to the audio preset retrieval module 220. The request may include an identifier corresponding to the audio preset. The audio preset retrieval module 220 may retrieve the audio preset from an audio preset storage 230. The audio preset storage 230 may be a database and/or any other type of storage service. After being retrieved from the audio preset storage 230, the audio preset may be transmitted to the user device 205. An image corresponding to the audio preset may also be transmitted to the user device 205. The image may be retrieved from an audio preset image storage 240, which may be a database and/or any other type of storage service.

If the user wishes to store an audio preset, the user authentication module 215 may forward the request to the audio preset creation module 225. The request may include the audio preset currently being used by the audio application 210. The audio preset creation module 225 may store the audio preset in the audio preset storage 230. An image corresponding to the audio preset may be stored in the audio preset image storage 240. Audio presets may be created during mastering using a DAW. An audio preset created using a DAW may be stored in the audio preset storage 230. An image corresponding to the audio preset created using the DAW may be stored in the audio preset image storage 240. Once an audio preset is saved, the audio preset can be recalled within the audio processing engine no matter where it is used. The audio preset can be used during production such as in the DAW. The audio preset can be used during reproduction such as on the audio application 210 executing on the user device 205.

An audio preset update notification module 235 may notify the user device 205 and/or audio application 210 that audio presets are available. The notification may indicate that new audio presets are available and/or that updated audio presets are available. The audio preset notification module 235 may maintain a lightweight network connection with the user device 205 in order to transmit notifications continuously. Rather than waiting until the audio application 210 is updated to receive updated audio presets, the audio preset notification module 235 allows the audio application 210 to continuously receive new and/or updated audio presets. New and/or modified audio presets may be pushed out to the audio application 210.

After the audio preset creation module 225 has stored a new audio preset or an update to an audio preset, the audio preset creation module 225 may notify the audio preset update notification module 235 that a new or updated audio preset is available. The audio preset update notification module 235 may then send notifications to one or more user devices 205 executing the audio application 210. An operator, such as a user that creates audio presets, may select which user devices 205 the audio preset creation module 225 may send a notification to. After creating an audio preset, the operator may upload the audio preset to the audio preset storage 230. The operator may then indicate that the audio preset should be released. The operator may select which users the audio preset will be distributed to. For example, the operator may select to distribute the audio preset to all users who subscribe to a particular audio service 245. The users who subscribe to that audio service 245 may then receive a notification indicating that the new audio preset is available and/or the audio preset may be visible in a local audio preset library of the user.

The system 200 may collect and/or store analytics on user engagement with the audio presets stored in the audio preset storage 230. The analytics may include, for each audio preset, number of times listened to, songs listened to with the audio preset, number of times the audio preset was purchased, number of times the audio preset was shared, associated classified music information retrieval (MIR) data, etc. The system 200 may include a dashboard that displays these analytics to the creator of the audio preset.

The user device 205 may store one or more audio presets and/or corresponding images. The audio presets and/or images may be encrypted. The audio processing engine may decrypt the encrypted audio presets and/or images. Each time the audio preset update notification module 235 signals to the user device 205 that a new and/or updated audio preset is available, the user device 205 may retrieve the new and/or updated audio preset. The corresponding image for the audio preset may be retrieved as well.

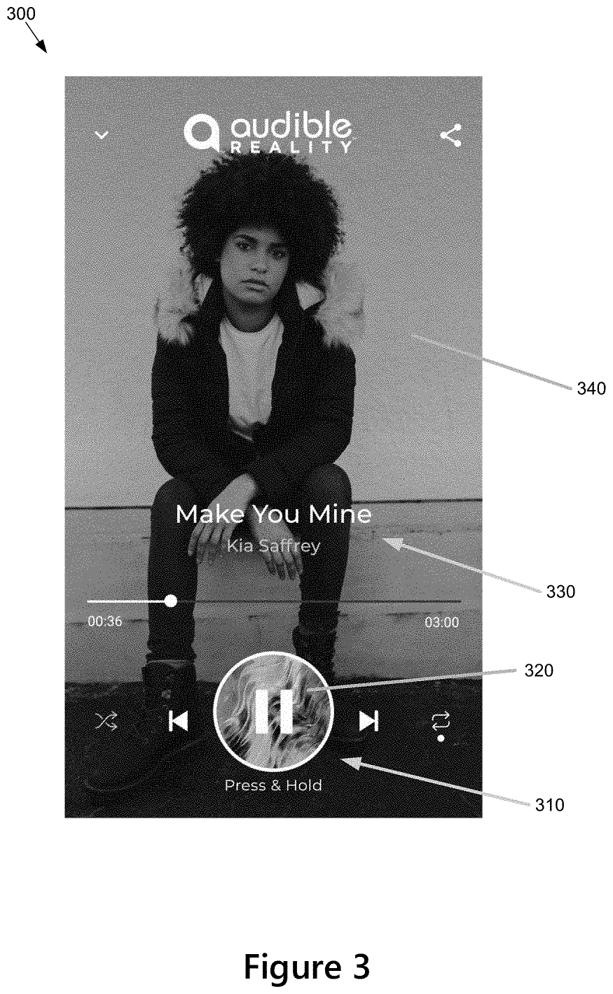

FIG. 3 illustrates a user interface 300 for the audio application 210 in accordance with various embodiments of the present technology. It should be understood that the user interface 300 is exemplary, and that various modifications may be made to the user interface 300 or other alternative user interfaces may be used instead of the user interface 300.

The user interface 300 may be displayed when an audio track, such as a song, is being played. The text 330 and image 340 may correspond to the audio track currently being played. The text 330 may comprise a title and/or artist of the audio being played. The image 340 may comprise an image associated with the audio, such as an album cover, book cover, or any other image associated with the audio.

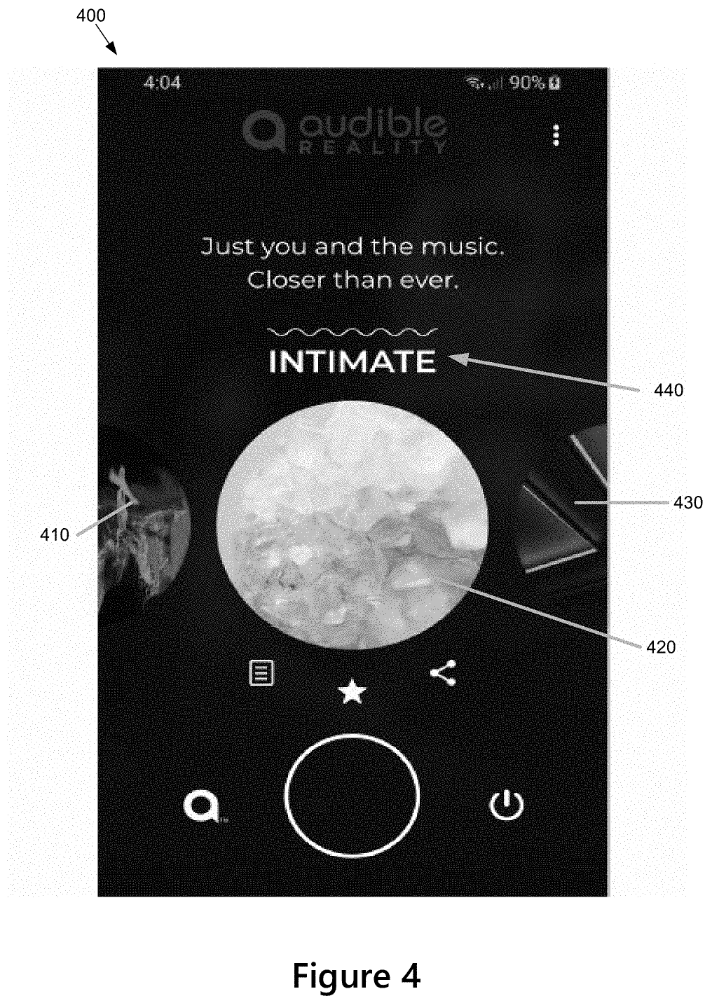

The user interface 300 may include a button 310. The button 310 may comprise a selectable element. The button 310 may be used to play and/or pause the audio. The audio may be traditional audio or an audio stream output by an audio processing engine, such as a 3D audio stream. An image 320 may be overlaid on the button 310. The image 320 may correspond to an audio preset currently being applied by the audio processing engine. The image 320 may provide, to the user, a visual indication of the audio preset that is currently being applied to the audio processing engine. In order to change the audio preset the user may select the button 310. The button 310 may cause different actions to be performed depending on how the user selects the button 310. A short-press of the button 310 may cause the audio to play or pause. A long-press of the button 310 may indicate that the user wishes to select a different audio preset or deactivate the audio processing engine. After selecting the button 310, audio presets may be displayed, such as by the carousel display illustrated in FIG. 4.

FIG. 4 illustrates a user interface 400 for selecting an audio preset in accordance with various embodiments of the present technology. In the interface 400, elements 410, 420 and 430 correspond to different audio presets that may be selected. Each of the elements 410, 420, and 430 has an image overlaid on the element, where the image corresponds to the audio preset associated with the element 410, 420, or 430. The element 420 is enlarged to indicate that this is the currently selected audio preset. Text 440 corresponds to the currently selected audio preset. The text 440 may include a name and/or author corresponding to the currently selected audio preset.

The interface 400 may comprise a carousel interface, where the user may be able to scroll through the elements 410, 420, and 430. If the user were to swipe to the left on the interface, the element 410 might no longer be shown, the element 420 might replace the element 410, the element 430 may replace the element 420 and become the currently selected audio preset, and another element (not shown) may replace the element 430. The currently selected element 420 may be applied to the audio processing engine processing the currently playing audio. As the user rotates through the carousel in the interface 400, different audio presets may be applied to the audio processing engine. In some instances the user might not have access to an audio preset, such as if the audio preset may be purchased and the user has not purchased that audio preset. In that case the user may be presented with a demonstration of the audio preset by applying the audio preset to the audio processing engine for a predetermined maximum period of time, such as fifteen seconds. The user may then decide whether they wish to purchase the audio preset.

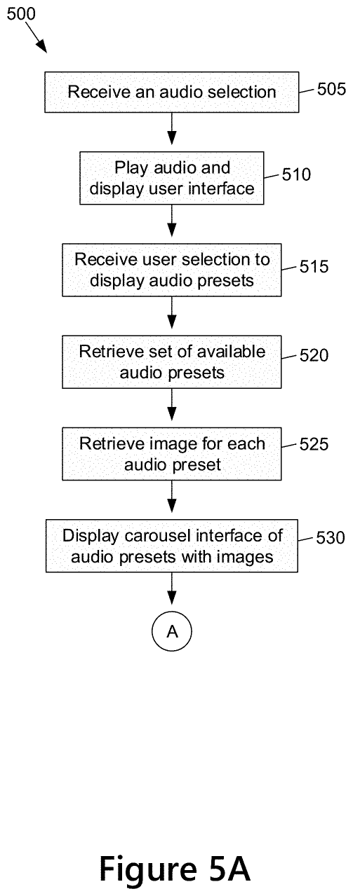

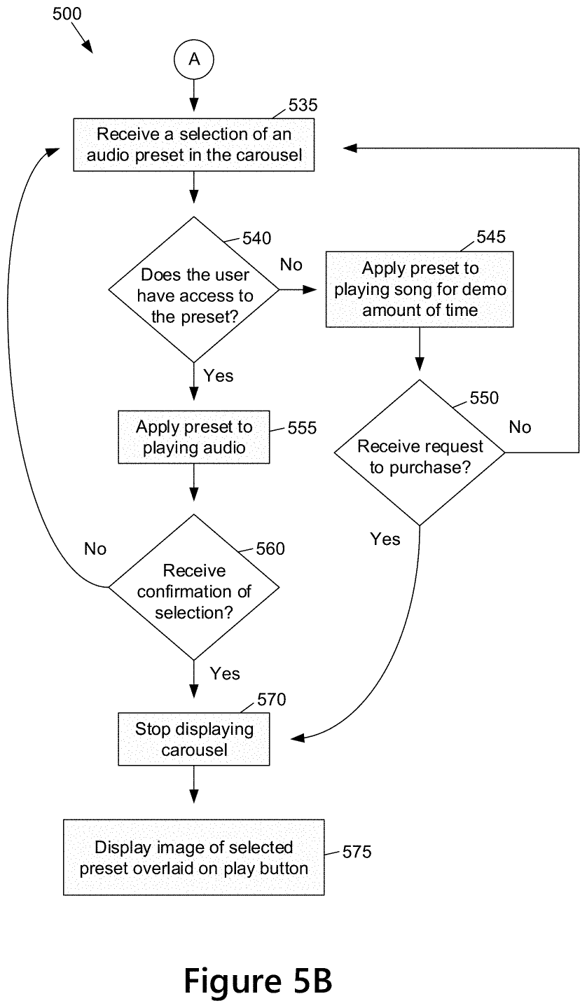

FIGS. 5A-B illustrate a flow diagram of a method 500 for selecting an audio preset in accordance with various embodiments of the present technology. In one or more aspects, the method 500 or one or more steps thereof may be performed by a computing system, such as the computing environment 100. The method 500 or one or more steps thereof may be embodied in computer-executable instructions that are stored in a computer-readable medium, such as a non-transitory mass storage device, loaded into memory and executed by a CPU. The method 500 is exemplary, and it should be understood that some steps or portions of steps in the flow diagram may be omitted and/or changed in order.

At step 505 an audio selection may be received. The selection may comprise an indication of an audio track that a user wishes to listen to. The audio selection may comprise an indication of a song, podcast, audiobook, or any other type of audio. Rather than selecting audio, a video may be selected, and the audio of that video may be processed by the audio processing engine using the steps described herein. The audio track may be selected using the audio application 210. A URL corresponding to an audio track may be selected.

At step 510 the audio corresponding to the selection received at step 505 may be played. The audio may be output by an application configured to execute and/or communicate with an audio processing engine. The audio may be output to a speaker, wireless audio device, headphones, and/or any other device for playing audio. A user interface, such as the interface 300, may be displayed. The audio may be retrieved and/or streamed from a third-party audio service, such as the audio service 245. The audio may be stored on a device, such as the user device 205.

At step 515 a user selection to display audio presets may be received. The user may select a selectable element on the displayed user interface, select a physical button on a device, provide a voice command, and/or use any other method for indicating a selection. For example the user may long-press the button 310 in the interface 300 to indicate that the user wishes to display available audio presets.

At step 520 a set of available audio presets may be retrieved. The set of available audio presets may be stored locally, such as by the audio application 210. The set of available audio presets may be retrieved from a remote location, such as the audio preset storage 230. The audio presets may be encrypted. A list of the available audio presets may be retrieved. The list may include, for each audio preset, a title, author, and/or any other information describing the audio preset. The set of available audio presets may be selected and/or retrieved based on a user ID, application version, application state, deep link, conversion point (such as purchase history) and/or other means.

The set of available audio presets may include audio presets that are automatically generated. For example an “AI” preset may be included in the list of available audio presets. The “AI” audio preset may be generated using a machine learning algorithm (MLA) such as an MLA based on one or more neural networks. The MLA may receive, as input, the currently played audio, information regarding the user, and/or other information relevant for generating an audio preset. The MLA may output an audio preset.

At step 525 an image may be retrieved for each of the available audio presets. The images may be stored locally and/or retrieved from a remote location, such as the audio preset image storage 240.

At step 530 some or all of the available audio presets may be displayed. A carousel interface, such as the interface 400, may be used to display the audio presets. The image associated with each audio preset may be displayed. The user may be able to scroll through the available audio presets, search for an audio preset, filter audio presets such as by theme, genre, or author, and/or use any other method for browsing the audio presets. The set of audio presets to display may be selected based on a user ID, application version, application state, deep link, conversion point (such as purchase history) and/or other means.

At step 535 a selection of an audio preset may be received. If a carousel user interface is displayed, a highlighted audio preset may be the selected audio preset. The highlighted preset may be enlarged and/or located in the center of the display. For example in the interface 400 the element 420 corresponds to the currently selected preset. The selected preset may be an audio preset that the user has interacted with or selected in any other manner. In order to select an audio preset, the user may place an image associated with the audio preset in a central portion of the carousel user interface.

At step 540 a determination may be made as to whether the user has access to the selected audio preset. Audio presets may be freely available, available for purchase, and/or may be available as part of an audio preset subscription. The audio preset subscription may provide access to multiple audio presets. The user authentication module 215 may indicate whether the user has access to the selected audio preset. If the audio preset is stored on the user device 205, an indication may be stored with the audio preset indicating whether the user has access to the audio preset.

If the user does not have access to the audio preset, at step 545 the user may be provided a demonstration of the audio preset for a limited amount of time. The audio processing engine may apply the audio preset up to a predetermined maximum time. For example the audio preset may be applied for up to fifteen seconds. After that amount of time, the audio preset might no longer be applied by the audio processing engine. The audio processing engine may stop generating the audio stream, and the audio being output may revert to the audio without any effects applied by the audio processing engine, such as without 3D effects. The user may be presented with an option to purchase the audio preset and/or purchase a subscription including the audio preset.

At step 550 the user may select whether they wish to purchase the audio preset, purchase a subscription including the audio preset, or select another audio preset. If the user does not wish to purchase the audio preset or a subscription including the audio preset, the user may wish to select another audio preset at step 535 such as by scrolling the carousel to select another audio preset.

If, at step 550, the user does wish to purchase the audio preset or a subscription, the user may be presented with a confirmation interface to complete the transaction and the method 500 may then continue to step 570.

Returning now to step 540, if the user does have access to the selected audio preset, such as if the audio preset is freely available, if the user has previously purchased the audio preset, or if the user has purchased a subscription including the audio preset, the preset may be applied to the audio processing engine at step 555 for an unlimited amount of time.

At step 560 the user may either confirm that they wish to select the currently selected audio preset or they may select another audio preset. The user may select another audio preset, such as by scrolling the carousel to highlight another audio preset. If the selects another audio preset, the method 500 may proceed to step 535.

At step 560 the user may confirm that they wish to apply the currently selected audio preset. In the user interface 400, the user may confirm the currently selected audio preset by selecting the element 420. If the user has confirmed that they wish to continue applying the selected audio preset, the carousel or other audio preset selection interface may stop being displayed at step 570. At step 575 an interface may be displayed with an indicator of the selected audio preset, such as the image associated with the selected audio preset. At steps 570 and 575 the user interface may switch from the interface 400 to the interface 300. The image of the selected audio preset may be overlaid on the button 310. The user may then continue to listen to the audio stream generated by applying the selected audio preset to the audio processing engine, modify the selected audio preset, or select a different audio preset.

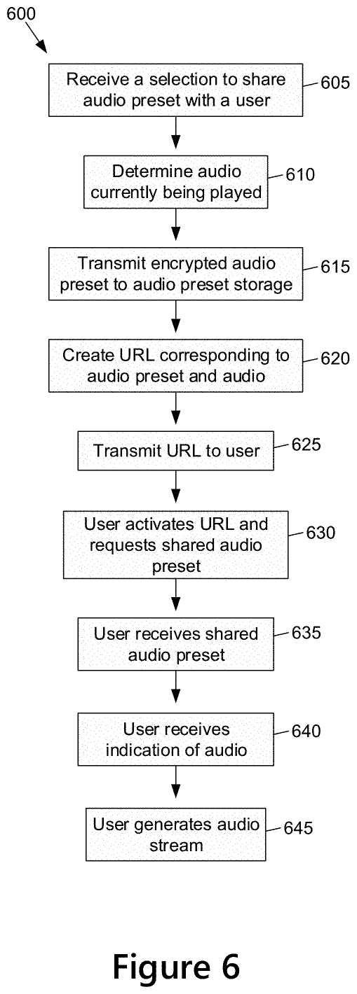

FIG. 6 illustrates a flow diagram of a method 600 for sharing an audio preset in accordance with various embodiments of the present technology. In one or more aspects, the method 600 or one or more steps thereof may be performed by a computing system, such as the computing environment 100. The method 600 or one or more steps thereof may be embodied in computer-executable instructions that are stored in a computer-readable medium, such as a non-transitory mass storage device, loaded into memory and executed by a CPU. The method 600 is exemplary, and it should be understood that some steps or portions of steps in the flow diagram may be omitted and/or changed in order.

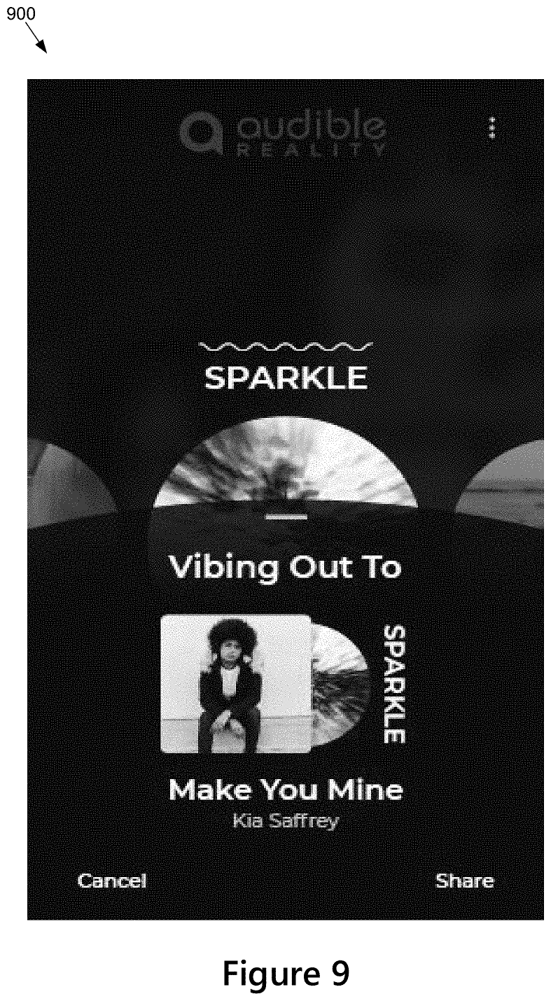

At step 605 a user selection may be received to share an audio preset with another user or other users. The user selection may be received while the user is playing an audio track. The audio currently being output may be an audio stream output by an audio processing engine. The audio preset may be applied to the audio processing engine. The user may wish to share, with another user, the audio preset that they are currently using and/or the audio track that they are currently playing. The user may indicate that they wish to share the audio preset by selecting an element in a user interface, such as a button labeled “share.” The interface 900, illustrated in FIG. 9 and described in further detail below, is an example of an interface that may be displayed to a user when the user selects to share an audio preset.

At step 610 a determination may be made as to the audio track currently being played. A title, artist, and/or other indicator of the audio track currently being played may be determined. A URL corresponding to the audio track may be determined. The URL may point to the audio track at a third-party audio service. The audio application 210 and/or audio service 245 may provide an indicator of the audio track currently being played.

At step 615 the currently applied audio preset may be transmitted to an audio preset storage. The audio preset may be transmitted in an encrypted format. A title, author, image and/or any other information corresponding to the audio preset may be transmitted and associated with the audio preset. The audio preset may be transmitted in a request to the user authentication module 215. The user authentication module 215 may transmit the audio preset to the audio preset creation module 225. The audio preset creation module 225 may store the audio preset in the audio preset storage 230. An indication of the audio track currently being played may be transmitted. The indication of the audio track may be associated with the audio preset.

Rather than transmitting the audio preset, an indicator of the audio preset may be transmitted. The audio preset may already be stored in the audio preset storage 230. In that case an indicator of the audio preset may be transmitted, rather than transmitting the audio preset again to the audio preset storage. For example a unique identifier corresponding to the audio preset may be transmitted.

At step 620 a URL corresponding to the audio preset and the audio may be created. The URL may comprise a unique identifier associated with the shared audio preset and/or audio. The URL may point to a location that, when accessed, causes the device accessing the URL to play the audio using the audio preset. The URL may be generated by and/or received by the audio application 210.

At step 625 the URL may be transmitted to another user. The URL may be transmitted using a messaging service, via email, or via any other method of transmitting a URL. If the other user is a user of the audio application 210 and/or system 200, the URL may be pushed directly to the audio application 210 of the other user.

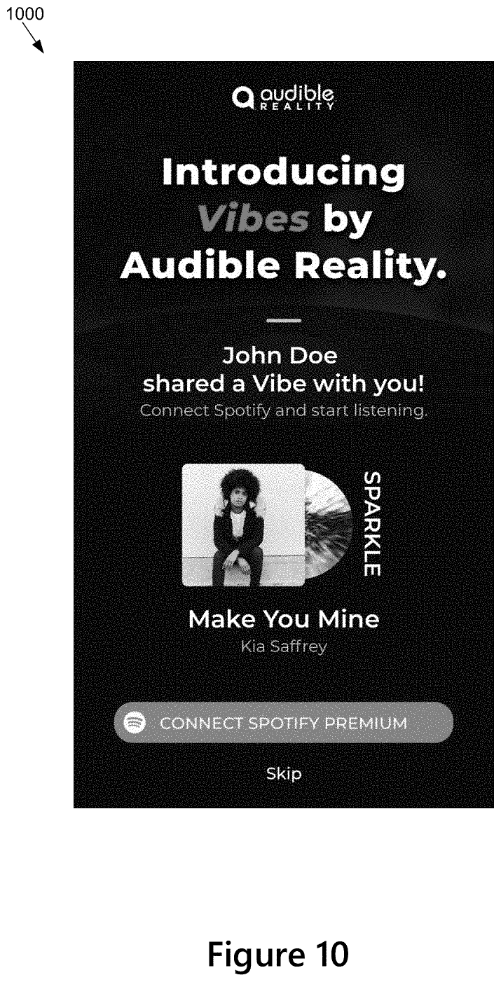

At step 630 the user that received the URL may access the URL such as by inputting the URL to a web browser application. The URL may cause the user to request the shared audio preset. Activating the URL may cause the audio application 210 to open on the user's device. The audio application 210 may then request the shared audio preset, such as by transmitting a request to the user authentication module 215. The request may comprise a portion of the URL, such as a unique identifier in the URL. The interface 1000, illustrated in FIG. 10 and described in further detail below, is an example of an interface that may be displayed to the user that received the URL after the user accesses the URL.

If the user's device does not have the audio application 210 installed, the URL may cause a page to open allowing the user to download the audio application 210. For example an application store or other web page may be displayed allowing the user to download and install the audio application 210. When the audio application 210 is installed, the audio preset corresponding to the URL may be requested.

At step 635 the audio preset may be received by the user's device. The audio preset may be encrypted. The user's device may also receive an image corresponding to the audio preset. The audio preset may be received from the audio preset storage 230. The corresponding image may be received from the audio preset image storage 240.

At step 640 the user's device may receive an indication of the audio track. The indication may comprise a link to the audio track at a third-party audio service, such as a third-party audio service used by the sharing user. The indication may comprise a title, artist, or other identifying information for the audio track. The user's device may use the indication to retrieve the audio track. The audio application 210 may retrieve the audio track from the audio service 245.

At step 645 the user's device may output an audio stream using the shared audio preset and the audio track. The shared audio preset may be applied to an audio processing engine. The audio track may be input to the audio processing engine and the audio processing engine may output an audio stream. In this manner the user may be able to listen to the same audio track using the same audio preset as the user that shared the audio preset.

In some instances a user may wish to share an audio preset without sharing a corresponding audio track. In that case, the steps 610 and 640 might be skipped. The user receiving the shared audio preset may receive the preset and then select an audio track to be played. The audio track may then be input to the audio processing engine using the shared audio preset to generate an audio stream.

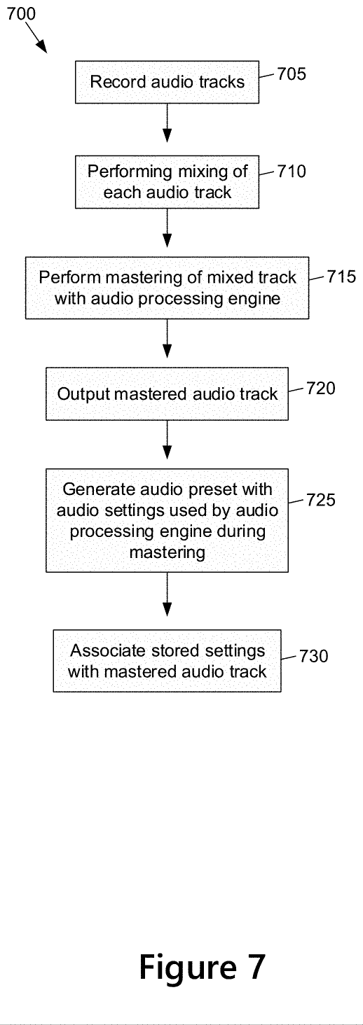

FIG. 7 illustrates a flow diagram of a method 700 for storing audio settings in accordance with various embodiments of the present technology. In one or more aspects, the method 700 or one or more steps thereof may be performed by a computing system, such as the computing environment 100. The method 700 or one or more steps thereof may be embodied in computer-executable instructions that are stored in a computer-readable medium, such as a non-transitory mass storage device, loaded into memory and executed by a CPU. The method 700 is exemplary, and it should be understood that some steps or portions of steps in the flow diagram may be omitted and/or changed in order.

At step 705 one or more audio tracks may be recorded. The audio tracks may comprise audio tracks recorded while performing a song, recording an audiobook, preparing for a radio broadcast or podcast, filming a video, etc. Each audio track may include audio from one or more instruments and/or vocals.

At step 710 each of the audio tracks may be mixed, such as by a mixing engineer. During mixing, each audio track may be adjusted such as by passing the track through one or more filters, normalizing each track, adding various effects to the track, etc. An audio processing engine may be used during the mixing process. The mixing engineer may input the track to the audio processing engine, and the audio processing engine may output an audio stream. The mixing engineer may listen to the audio stream while performing the mixing. After mixing each of the tracks, a mixed audio track may be generated.

At step 715 mastering may be performed on the mixed track. A mastering engineer may perform the mastering. During mastering, adjustments may be made to the mixed track, such as adjusting the levels, compression, and/or any other edits to the mixed track. The mastering engineer may use the audio processing engine during mastering of the track. The mastering engineer may listen to an audio stream of the track being output by the audio processing engine.

At step 720 a mastered audio track may be output. The mastered audio track may be a final mastered audio file generated by applying filters, effects, equalizers, compressors, etc. to the mixed tracks. The mastered audio track may be generated and output by a DAW.

At step 725 the settings applied to the audio processing engine during mixing and/or mastering may be stored. The settings may correspond to various adjustable parameters of the audio processing engine. The settings may be stored in a file that is in a format readable by the audio processing engine. The settings may be stored as an audio preset for the audio processing engine. The audio preset may allow an end-user to modify the parameters set by the mixing engineer and/or mastering engineer during mixing and/or mastering. The settings may be output by an application interacting with the DAW. The application interacting with the DAW may incorporate an audio processing engine. The mixing engineer and/or mastering engineer may adjust parameters of the audio processing engine during mixing and/or mastering. Those parameters may be stored in the audio preset.

At step 730 the stored settings may be associated with the final audio track. The stored settings may be stored as an audio preset and the audio preset may be associated with the final audio track. The audio preset may then be used by any playback device executing the audio processing engine. A listener may then apply the audio preset while listening to the audio track. Because the settings used during mixing and/or mastering are being applied to the audio processing engine, the audio stream output by the audio processing engine may be consistent with the audio stream output during the mixing and/or mastering process.

The audio preset may contain saved parameters and control settings for the audio signal processing chain used in the audio production process. The listener may modify the settings of the audio preset. By modifying the settings of the audio preset, the listener may be able to make the same adjustments to the audio that were available during mixing and/or mastering. The listener may be able to add, remove, and/or adjust filters, effects, equalizers, compressors, etc. that were applied during mixing and/or mastering.

The audio preset generated at step 725 may be associated with the mastered audio track generated at step 720. An identifier of the audio track may be stored in the audio preset. The audio preset may be locked to the audio track. In that case, an indication may be stored in the audio preset indicating that the audio preset should not be applied to any other audio tracks. Otherwise, the audio preset may be unlocked, in which case an end-user may apply the audio preset to any audio track.

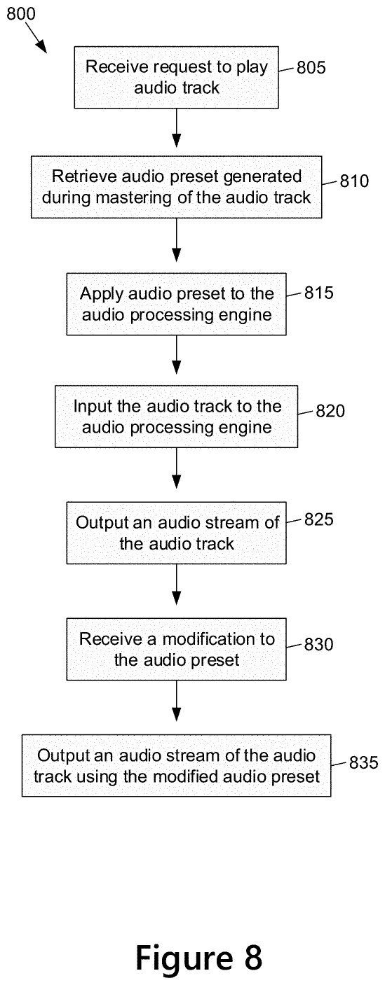

FIG. 8 illustrates a flow diagram of a method 800 for outputting an audio stream in accordance with various embodiments of the present technology. In one or more aspects, the method 800 or one or more steps thereof may be performed by a computing system, such as the computing environment 100. The method 800 or one or more steps thereof may be embodied in computer-executable instructions that are stored in a computer-readable medium, such as a non-transitory mass storage device, loaded into memory and executed by a CPU. The method 800 is exemplary, and it should be understood that some steps or portions of steps in the flow diagram may be omitted and/or changed in order.

At step 805 a request may be received to play an audio track. Actions taken at step 805 may be similar to those taken at step 505, described above. Audio settings may be associated with the audio track. The audio settings may be stored as an audio preset. The audio settings may be settings that were used when mixing and/or mastering the audio track.

At step 810 the audio settings used during mixing and/or mastering of the audio track may be retrieved. The audio settings may be in the format of an audio preset. The audio settings may be settings for configurable parameters of an audio processing engine. The audio settings may be retrieved from the audio preset storage 230. An image corresponding to the audio settings may be retrieved from the audio preset image storage 240. The audio preset may have been output by a DAW and may contain settings used by the DAW during mastering of the audio track.

At step 815 the retrieved audio settings may be applied to an audio processing engine. The configurable parameters of the audio processing engine may be adjusted to match the retrieved audio settings. If the retrieved audio settings are stored in an audio preset, the audio preset may be applied to the audio processing engine.

At step 820 the audio track may be input to the audio processing engine. The audio track may be retrieved from an audio source, such as the audio service 245. All or a portion of the audio track may be input to the audio processing engine. For example if the audio track is being streamed, the downloaded portion of the audio track may be input to the audio processing engine. As further portions of the audio track are downloaded, those additional portions may be input to the audio processing engine.

At step 825 the audio processing engine may output an audio stream corresponding to the audio track. Because the same settings are applied to the audio processing engine as were used during mixing and/or mastering, the playback of the audio track will match the playback of the mixing and/or mastering engineers.

At step 830 the listener may input a modification to the audio preset. The audio preset may include various configurable parameters. The user may modify the configurable parameters. The configurable parameters may control settings used during mastering of the audio track. By modifying the audio preset, the listener may be able to make the same adjustments to the audio track that the mastering engineer was able to make when mastering the audio track.

At step 835 the audio stream may be output using the audio preset that was modified by the listener. The modified audio preset may be applied to the audio processing engine. The listener may continue to adjust the audio preset, and the output audio may respond accordingly.

FIG. 9 illustrates a user interface 900 for sharing an audio preset in accordance with various embodiments of the present technology. As discussed above, a user may share, with a second user, an audio preset paired with audio that the user is listening to. The interface 900 displays the audio that the user is currently listening to. The interface 900 also displays the audio preset that the user has selected to be applied to the audio. The interface 900 provides a selectable element that the user may select to share the audio and audio preset with a second user.

FIG. 10 illustrates a user interface 1000 for receiving a shared audio preset in accordance with various embodiments of the present technology. The interface 1000 is an example of an interface that may be displayed to a second user receiving shared audio and/or a shared audio preset. The interface 1000 may allow the second user to play the shared audio with the shared audio preset. The interface 1000 may be shown after the second user selects a URL.

While some of the above-described implementations may have been described and shown with reference to particular acts performed in a particular order, it will be understood that these acts may be combined, sub-divided, or re-ordered without departing from the teachings of the present technology. At least some of the acts may be executed in parallel or in series. Accordingly, the order and grouping of the act is not a limitation of the present technology.

It should be expressly understood that not all technical effects mentioned herein need be enjoyed in each and every embodiment of the present technology.

As used herein, the wording “and/or” is intended to represent an inclusive-or; for example, “X and/or Y” is intended to mean X or Y or both. As a further example, “X, Y, and/or Z” is intended to mean X or Y or Z or any combination thereof.

The foregoing description is intended to be exemplary rather than limiting. Modifications and improvements to the above-described implementations of the present technology may be apparent to those skilled in the art.

1. A method comprising:
receiving user input indicating a selection of an audio track;
retrieving an audio preset corresponding to the audio track, wherein the audio preset was created by an audio processing engine, wherein the audio preset comprises parameters for the audio processing engine, and wherein the parameters correspond to an audio signal processing chain used to create the audio track;
applying the audio preset to the audio processing engine;
generating, by the audio processing engine and based on the audio track, an audio stream; and
outputting the audio stream.

2. The method of claim 1, further comprising:
receiving user input modifying the audio preset;
applying the modified audio preset to the audio processing engine;
generating, by the audio processing engine and based on the audio, a second audio stream; and
outputting the second audio stream.

3. The method of claim 1, further comprising
displaying a carousel user interface comprising a plurality of images corresponding to audio presets; and
receiving, via the carousel user interface, a selection of the audio preset.

4. The method of claim 1, further comprising determining whether a user has access to the audio preset, and wherein applying the audio preset to the audio processing engine comprises applying the audio preset to the audio processing engine after determining that the user has access to the audio preset.

5. The method of claim 1, further comprising determining whether a user has access to the audio preset, and wherein outputting the audio stream comprises outputting the audio stream for up to a predetermined amount of time after determining that the user does not have access to the audio preset.

6. A method comprising:
receiving user input indicating a selection of an audio track;
outputting audio corresponding to the audio track;
displaying a user interface for controlling playback of the audio track;
receiving a selection to display audio presets;
retrieving a plurality of available audio presets, wherein each audio preset comprises parameters for an audio processing engine, and wherein the parameters correspond to an audio signal processing chain used to create an audio track;
retrieving a plurality of images, wherein each image of the plurality of images corresponds to a respective audio preset of the plurality of available audio presets;
displaying a carousel user interface comprising at least one image of the plurality of images;
receiving, via the carousel user interface, a selection of an audio preset of the plurality of available audio presets;
determining whether a user has access to the audio preset;
after determining that the user has access to the audio preset, applying the audio preset to the audio processing engine;
generating, by the audio processing engine and based on the audio track, an audio stream; and
outputting the audio stream.

7. The method of claim 6, further comprising:
receiving, via the carousel user interface, a selection of a second audio preset of the plurality of available audio presets;
applying the second audio preset to the audio processing engine;
generating, by the audio processing engine and based on the audio, a second audio stream; and
outputting the second audio stream.

8. The method of claim 6, wherein determining whether the user has access to the audio preset comprises determining whether the user has paid a fee associated with the audio preset.

9. The method of claim 6, wherein each audio preset of the plurality of available audio presets comprises settings for one or more adjustable parameters of the audio processing engine.

10. The method of claim 6, wherein receiving the selection of the audio preset comprises receiving an indication that the user has placed an image corresponding to the audio preset in a central portion of the carousel user interface.

11. The method of claim 6, wherein the carousel interface comprises a scrollable interface for scrolling through the plurality of images.

12. The method of claim 6, further comprising:
prior to determining that the user has access to the audio preset, determining that the user does not have access to the audio preset;
outputting the audio stream for up to a predetermined amount of time;
after the predetermined amount of time, reverting to outputting the audio corresponding to the audio track;
receiving a confirmation that the user has purchased the audio preset; and
after receiving the confirmation, outputting the audio stream.

13. The method of claim 12, further comprising receiving a user selection to subscribe to a subscription comprising the audio preset.

14. A system comprising:
at least one processor, and
memory storing a plurality of executable instructions which, when executed by the at least one processor, cause the system to:
receive user input indicating a selection of an audio track;
retrieve an audio preset corresponding to the audio track, wherein the audio preset was created by an audio processing engine, wherein the audio preset comprises parameters for the audio processing engine, and wherein the parameters correspond to an audio signal processing chain used to create the audio track;
apply the audio preset to the audio processing engine;
generate by the audio processing engine and based on the audio track, an audio stream; and
output the audio stream.

15. The system of claim 14, wherein the instructions, when executed by the at least one processor, cause the system to:
receive user input modifying the audio preset;
apply the modified audio preset to the audio processing engine;
generate, by the audio processing engine and based on the audio, a second audio stream; and
output the second audio stream.

16. The system of claim 14, wherein the instructions, when executed by the at least one processor, cause the system to:
display a carousel user interface comprising a plurality of images corresponding to audio presets; and
receive, via the carousel user interface, a selection of the audio preset.

17. The system of claim 14, wherein the instructions, when executed by the at least one processor, cause the system to:
determine whether a user has access to the audio preset; and
after determining that the user has access to the audio preset, apply the audio preset to the audio processing engine.

18. The system of claim 14, wherein the instructions, when executed by the at least one processor, cause the system to:
determine whether a user has access to the audio preset; and
after determining that the user does not have access to the audio preset, output the audio stream for up to a predetermined amount of time.

19. The system of claim 18, wherein the instructions, when executed by the at least one processor, cause the system to after the predetermined amount of time, revert to outputting audio corresponding to the audio track.

20. The system of claim 19, wherein the instructions, when executed by the at least one processor, cause the system to:
receive a confirmation that the user has purchased the audio preset; and
after receiving the confirmation, output the audio stream.
